(19) United States
(12) Patent Application Publication
(10) Pub. No.: US 2015/0155297 A1
(43) Pub. Date: Jun. 4, 2015

(54) METHODS OF FABRICATING SEMICONDUCTOR DEVICES HAVING DOUBLE-LAYERED BLOCKING INSULATING LAYERS

(71) Applicants: Dae-hong EOM, Hwaseong-si (KR); Dong-Chul YOO, Seongnam-si (KR); Kyung-Hyun KIM, Seoul (KR); Ki-Hyun HWANG, Seongnam-si (KR)

(72) Inventors: Dae-hong EOM, Hwaseong-si (KR); Dong-Chul YOO, Seongnam-si (KR); Kyung-Hyun KIM, Seoul (KR); Ki-Hyun HWANG, Seongnam-si (KR)

(21) Appl. No.: 14/315,906

(22) Filed: Jun. 26, 2014

(30) Foreign Application Priority Data
Nov. 29, 2013 (KR) 10-2013-0147755

(51) Int. Cl. H01L 27/115

(52) U.S. Cl. CPC H01L 27/11582

(57) ABSTRACT

Provided is a method of fabricating a semiconductor memory device. The method includes alternately stacking interlayer insulating layers and sacrificial layers on a substrate, forming a channel hole exposing the substrate through the interlayer insulating layers and the sacrificial layers, sequentially forming a blocking insulating layer, an electric charge storage layer and a channel layer on a substrate exposed on a sidewall of the channel hole and in the channel hole wherein the blocking insulating layer includes a first blocking insulating layer and a second blocking insulating layer, selectively removing the sacrificial layers to expose the first blocking insulating layer and then forming a gap, removing the first blocking insulating layer exposed in the gap, forming first blocking insulating patterns between the interlayer insulating layers and the second blocking insulating layer, and forming a gate electrode in the gap.

### CROSS-REFERENCE TO RELATED APPLICATION

This application claims priority under 35 U.S.C. §119 to Korean Patent Application No. 10-2013-0147755 filed on Nov. 29, 2013, the disclosure of which is hereby incorporated by reference in its entirety.

### BACKGROUND

1. Field

Embodiments of the inventive concepts relate to a semiconductor memory device having double-layered blocking insulating layers and a method of fabricating the same. For example, embodiments of the inventive concepts relate to a vertical-type NAND flash memory device and a method of fabricating the same.

2. Description of Related Art

A vertical-type NAND flash memory device may include a channel structure extending in a vertical direction on a substrate, and a plurality of interlayer insulating layers and a plurality of gate electrodes which are alternately stacked. The gate electrodes may be formed in a gap by removing a sacrificial layer interposed between the interlayer insulating layers to form the gap. Therefore, a process that removes the sacrificial layers between the interlayer insulating layers may be needed in fabricating a three-dimensional NAND flash memory device having a vertical channel. While removing the sacrificial layer, a blocking insulating layer formed on an outside wall of the channel structure including the vertical channel may be exposed, and the blocking insulating layer may be non-uniformly removed or damaged by a wet etchant that removes the sacrificial layer. Therefore, the characteristics of a semiconductor device may be degraded.

### SUMMARY

Embodiments of the inventive concepts provide a semiconductor memory device having double-layered blocking insulating layers.

Other embodiments of the inventive concepts provide a method of fabricating a semiconductor memory device having double-layered blocking insulating layers.

The technical objectives of the inventive concepts are not limited to the above disclosure; other objectives may become apparent to those of ordinary skill in the art based on the following descriptions.

A method of fabricating a semiconductor memory device in accordance with embodiments of the inventive concepts includes: alternately stacking interlayer insulating layers and sacrificial layers on a substrate; forming a channel hole exposing the substrate through the interlayer insulating layers and the sacrificial layers; sequentially forming a blocking insulating layer, an electric charge storage layer and a channel layer on the substrate exposed on a sidewall of the channel hole and in the channel hole, wherein the blocking insulating layer includes a first blocking insulating layer and a second blocking insulating layer; selectively removing the sacrificial layers to expose the first blocking insulating layer and forming a gap; removing the first blocking insulating layer exposed in the gap, and forming first blocking insulating patterns between the interlayer insulating layers and the second blocking insulating layer; and forming a gate electrode in the gap.

A method of fabricating a semiconductor memory device in accordance with other embodiments of the inventive concepts includes: alternately stacking a plurality of interlayer insulating layers and a plurality of sacrificial layers on a substrate; forming at least two channel holes exposing a first surface of the substrate through the interlayer insulating layers and the sacrificial layers; forming pillar structures in the channel holes, wherein each of the pillar structures includes a first blocking insulating layer, a second blocking insulating layer, an electric charge trap layer, a tunnel insulating layer, a vertical channel and a filling insulating layer; forming a trench passing through the interlayer insulating layers and the sacrificial layers between the pillar structures, wherein the trench exposes side surfaces of the interlayer insulating layers and the sacrificial layers and a second surface of the substrate; removing the sacrificial layers exposed in the trench and forming a gap; removing the first blocking insulating layer exposed in the gap, and exposing the second blocking insulating layer in the gap; forming a gate electrode in the gap; and forming a trench insulator in the trench.

A method of fabricating a semiconductor memory device in accordance with other embodiments of the inventive concepts includes: alternately stacking interlayer insulating layers and sacrificial layers on the substrate; forming a channel hole exposing the substrate through the interlayer insulating layers and sacrificial layers; forming a semiconductor pattern partially filling a lower portion of the channel hole; sequentially forming a blocking insulating layer, an electric charge storage layer and a channel layer on a sidewall of the channel hole and on the semiconductor pattern, wherein the blocking insulating layer includes a first blocking insulating layer and a second insulating layer; selectively removing the sacrificial layers to expose the first blocking insulating layer and a sidewall of the semiconductor pattern and forming a gap; removing the first blocking insulating layer exposed in the gap and forming a first blocking insulating patterns between the interlayer insulating layers and the second blocking layer, upper and lower surfaces of the first blocking insulating patterns being rounded to have a curved surface; and forming a gate electrode in the gap.

Details of other embodiments are included in the detailed description and drawings.

### BRIEF DESCRIPTION OF THE DRAWINGS

The foregoing and other features and advantages of the inventive concepts will be apparent from the more particular description of preferred embodiments of the inventive concepts, as illustrated in the accompanying drawings in which like reference numerals denote the same respective parts throughout the different views. The drawings are not necessarily to scale, emphasis instead being placed upon illustrating the principles of the inventive concepts. In the drawings:

FIG. 1A is a cross-sectional view showing a semiconductor device in accordance with embodiments of the inventive concepts;

FIG. 1B is an enlarged view of C region in FIG. 1A;

FIGS. 2, 3, 4, 5A, 6, 7A, 8A, 9, 10, 11A, 12A, 13A, 14 and 15 are cross-sectional views for describing a method of fabricating a semiconductor device in accordance with embodiments of the inventive concepts;

FIGS. 5B, 7B, 8B, 11B, 12B and 13B are enlarged views of C regions in FIGS. 5A, 7A, 8A, 11A, 12A and 13A, respectively;

FIG. 16A is a diagram conceptually illustrating a semiconductor module in accordance with embodiments of the inventive concepts; and

FIGS. 16B and 16C are block diagrams conceptually illustrating electronic systems in accordance with embodiments of the inventive concepts.

### DETAILED DESCRIPTION OF EXAMPLE EMBODIMENTS

Various embodiments will now be described more fully with reference to the accompanying drawings in which some embodiments are shown. These inventive concepts may, however, be embodied in different forms and should not be construed as limited to the embodiments set forth herein. Rather, these embodiments are provided so that this disclosure is thorough and complete and fully conveys the inventive concepts to those skilled in the art.

It will be understood that when an element or layer is referred to as being “on,” “connected to,” or “coupled with” another element or layer, it can be directly on, connected, or coupled to the other element or layer or intervening elements or layers may be present. In contrast, when an element is referred to as being “directly on,” “directly connected to,” or “directly coupled with” another element or layer, there are no intervening elements or layers present. Like numerals refer to like elements throughout. As used herein, the term “and/or” includes any and all combinations of one or more of the associated listed items.

The terminology used herein is for the purpose of describing particular embodiments only and is not intended to be limiting of the present inventive concepts. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the drawings, the sizes and relative sizes of layers and regions may be exaggerated for clarity. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. In the following explanation, the same reference numerals denote the same components throughout the specification.

It will be understood that, although the terms first, second, third, etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the present inventive concepts.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

Unless otherwise defined, all terms (including technical and scientific terms) used herein are to be interpreted as is customary in the art to which this invention belongs. It will be further understood that terms in common usage should also be interpreted as is customary in the relevant art and not in an idealized or overly formal sense unless expressly so defined herein.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

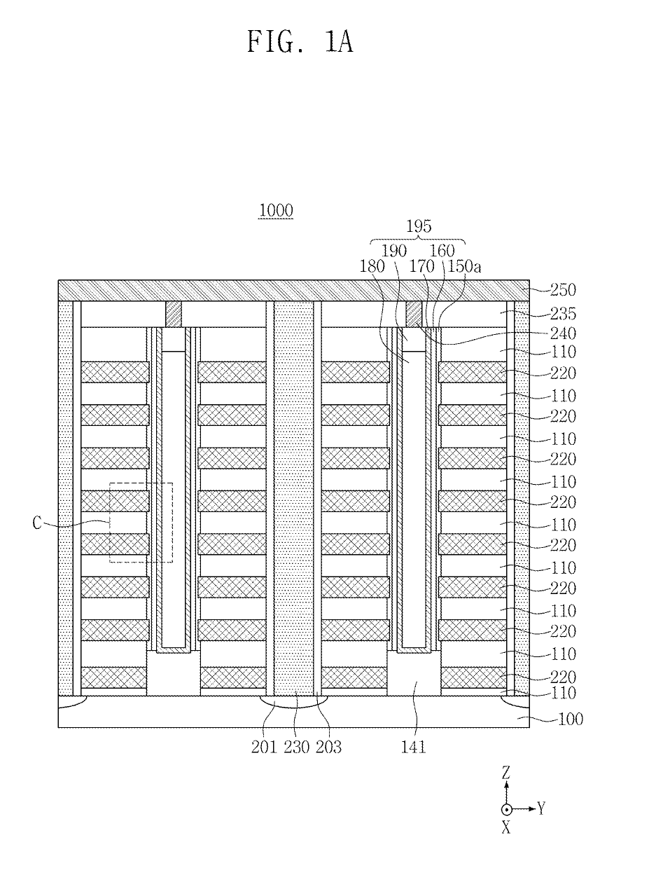

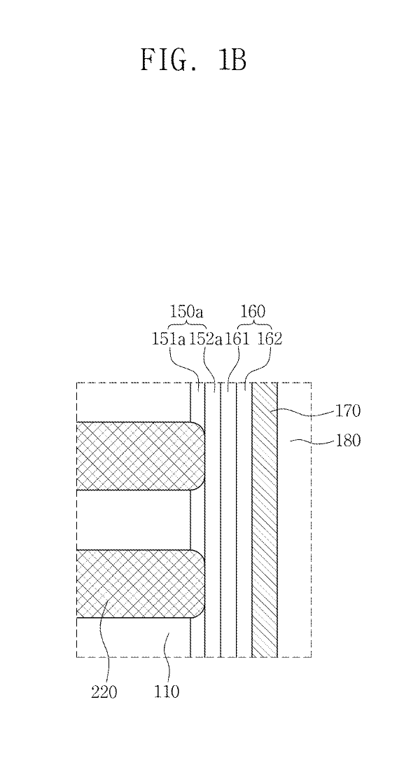

FIG. 1A is a cross-sectional view showing a semiconductor device in accordance with embodiments of the inventive concepts, and FIG. 1B is an enlarged view of C region in FIG. 1A.

Referring to FIGS. 1A and 1B, a semiconductor device 1000 in accordance with embodiments of the inventive concepts is may include a semiconductor pattern 141, a pillar structure 195 and gate electrodes 220 disposed on a substrate 100. The semiconductor device 1000 may further include interlayer insulating layers 110, a trench insulator 230 and a common source line 201. The semiconductor device 1000 may further include a capping insulating layer 235, a bit line contact 240 and a bit line 250 covering the interlayer insulating layer 110 and the pillar structure 195.

The substrate 100 may include a bulk silicon wafer, a germanium substrate, a silicon-germanium substrate, a silicon on insulator (SOI) wafer, etc.

The semiconductor pattern 141 may protrude in a Z direction on the substrate 100. The semiconductor pattern 141 may include single crystalline silicon or a silicon-germanium compound.

The pillar structure 195 may include a vertical channel 170, a filling insulating layer pattern 180, a channel pad 190, an electric charge storage layer 160 and a blocking insulating pattern 150a.

The vertical channel 170 having a cylinder shape on the semiconductor pattern 141 may protrude to extend in the Z direction. The bottom of the vertical channel 170 may be in contact with the semiconductor pattern 141. The vertical channel 170 may be electrically connected to the substrate 100 through the semiconductor pattern 141. The vertical channel 170 may include polycrystalline silicon.

The filling insulating layer pattern 180 may fill the inside of the vertical channel 170. The filling insulating layer pattern 180 may include an insulating material such as silicon oxide, silicon oxynitride or silicon nitride.

The channel pad 190 may be disposed on the filling insulating layer pattern 180. The channel pad 190 may be in direct contact with an upper sidewall of the vertical channel 170 and electrically connected thereto.

The electric charge storage layer 160 may include an electric charge trap layer 161 and a tunnel insulating layer 162. The electric charge trap layer 161 may be disposed on the tunnel insulating layer 162, and include a nitride such as silicon nitride. The tunnel insulating layer 162 may surround an outside sidewall of the vertical channel 170. The tunnel insulating layer 162 may include silicon oxide or silicon oxynitride.

The blocking insulating pattern 150a may include a first blocking insulating pattern 151a and a second blocking insulating pattern 152a. The second blocking insulating pattern 152a may be disposed on the electric charge trap layer 161, and include an oxide such as silicon oxide. The first blocking insulating pattern 151a may be disposed between the interlayer insulating layers 110 and the second blocking insulating pattern 152a, may include an oxide such as silicon oxide. The second blocking insulating pattern 152a may be denser than the first blocking insulating pattern 151a. For example, the first blocking insulating pattern 151a may include silicon oxide, and the second blocking insulating pattern 152a may include oxidized silicon or nitrogen-substituted silicon oxide in which nitrogen is substituted with oxygen. The nitrogen-substituted silicon oxide is changed into silicon oxide substantially changed by oxidizing silicon nitride. The second blocking insulating pattern 152a may have a thickness greater than or equal to the first blocking insulating pattern 151a. The second blocking insulating pattern 152a is vertically continued, and the first blocking insulating pattern 151a is vertically discontinued.

The gate electrodes 220 and the interlayer insulating layers 110 may surround a sidewall of the pillar structure 195 and extend in an X direction. A portion of the gate electrodes 220 in contact with the first blocking insulating pattern 151a may be rounded to have a curved surface. A distance from a side surface of the gate electrodes 220 to the vertical channel 170 may be shorter than a distance from a side surface of the interlayer insulating layer 110 to the vertical channel 170. The gate electrodes 220 disposed on the lowest portion may surround an outside wall of the semiconductor pattern 141. The electric charge storage layer 160 and the blocking insulating pattern 151a may be omitted between the gate electrodes 220 disposed on the lowest portion and the semiconductor pattern 141. The gate electrodes 220 may include a conductive material such as tungsten, copper or a metal silicide. The first blocking insulating pattern 151a and the second blocking insulating pattern 152a may be interposed between the interlayer insulating layers 110 and the electric charge storage layer 160. As shown in FIGS. 1A and 1B, the interlayer insulating layer 110 may be formed on one side surface of the first blocking insulating pattern 151a, and the second blocking insulating pattern 152a may be formed on the other side surface of the first blocking insulating pattern 151a. The gate electrodes 220 and the interlayer insulating layers 110 may be alternately stacked. The interlayer insulating layer 110 may include an insulating material such as silicon oxide, silicon nitride, silicon oxynitride, etc.

The trench insulator 230 may be disposed between the pillar structures 195 and vertically pass through the gate electrodes 220 and the interlayer insulating layers 110. The trench insulator 230 may be in contact with the substrate 100. The trench insulator 230 may extend along the X direction. A trench spacer 203 in contact with the gate electrodes 220 and the interlayer insulating layers 110 may be disposed on sidewalls of the trench insulator 230.

The common source line 201 may be formed in the substrate 100 to align with the trench insulator 230. The common source line 201 may include N-type impurities such as phosphorus or arsenic injected into the substrate 100.

The capping insulating layer 235 may be disposed on the vertical channel 170 and the channel pad 190. The capping insulating layer 235 may include silicon oxide.

The bit line contact 240 may be in contact with the channel pad 190 through the capping insulating layer 235. The bit line contact 240 may include a conductor such as silicon, metal silicide or a metal.

The bit line 250 may be disposed on the capping insulating layer 235 and the bit line contact 240 to extend in a Y direction. The bit line 250 may include a metal such as tungsten or copper.

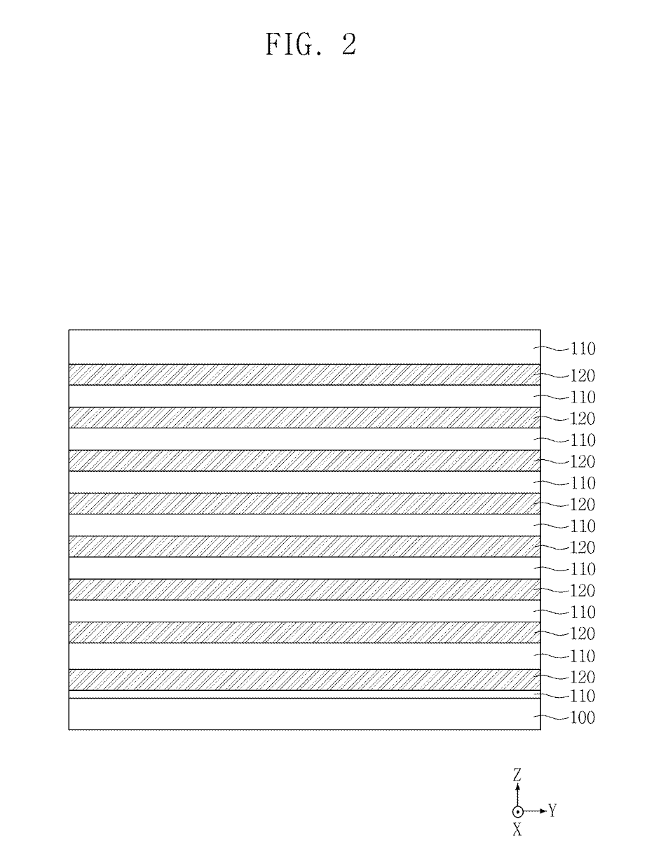

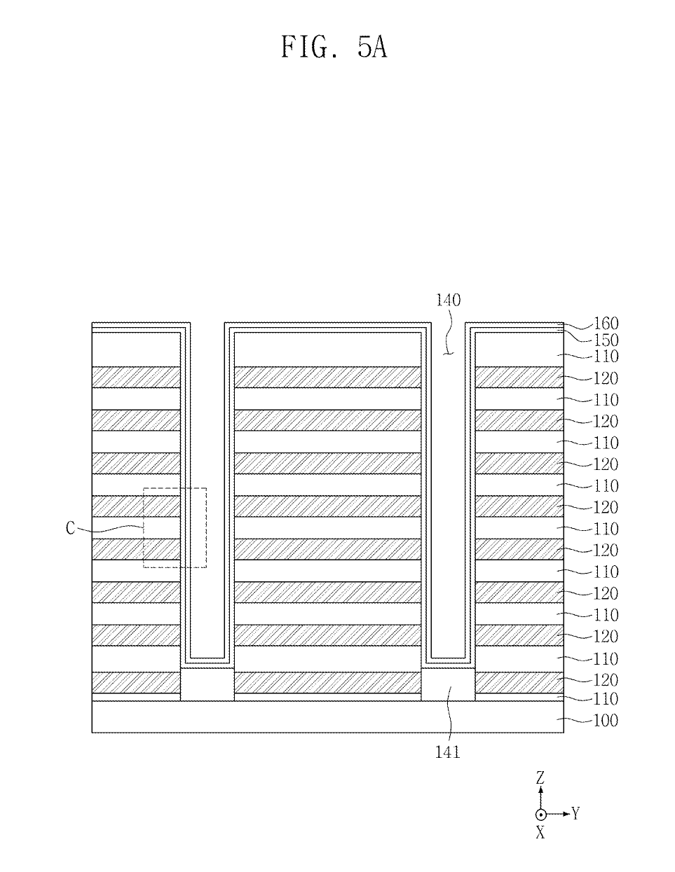

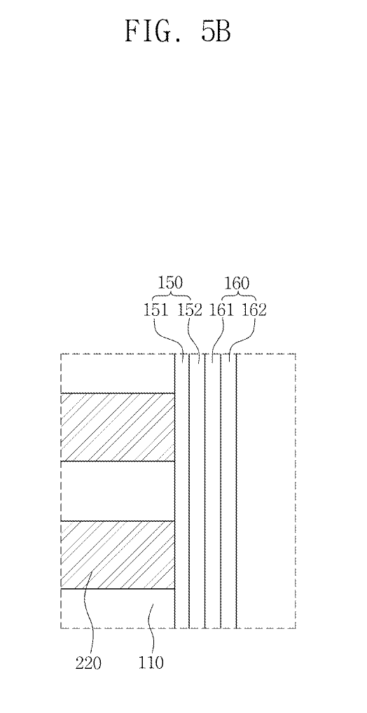

FIGS. 2, 3, 4, 5A, 6, 7A, 8A, 9, 10, 11A, 12A, 13A, 14 and 15 are cross-sectional views for describing a method of fabricating a semiconductor device in accordance with embodiments of the inventive concepts, and FIGS. 5B, 7B, 8B, 11B, 12B and 13B are enlarged views of C regions in FIGS. 5A, 7A, 8A, 11A, 12A and 13A, respectively.

Referring to FIG. 2, a method of fabricating a semiconductor device may include alternately and repeatedly stacking an interlayer insulating layer 110 and a sacrificial layer 120 on a substrate 100. Thus, a plurality of interlayer insulating layers 110 and a plurality of sacrificial layers 120 may be alternately stacked on the substrate 100 in a Z direction. The substrate 100 may include a semiconductor material such as silicon, germanium, etc.

The interlayer insulating layers 110 may include an insulating material such as silicon oxide. The interlayer insulating layers 110 may have different thicknesses. For example, the interlayer insulating layer 110 disposed on the lowest portion may have a smaller thickness than other interlayer insulating layers 110.

The sacrificial layers 120 may include a material having an etch selectivity from the interlayer insulating layers 110. For example, the sacrificial layers 120 may include an insulating material such as silicon nitride.

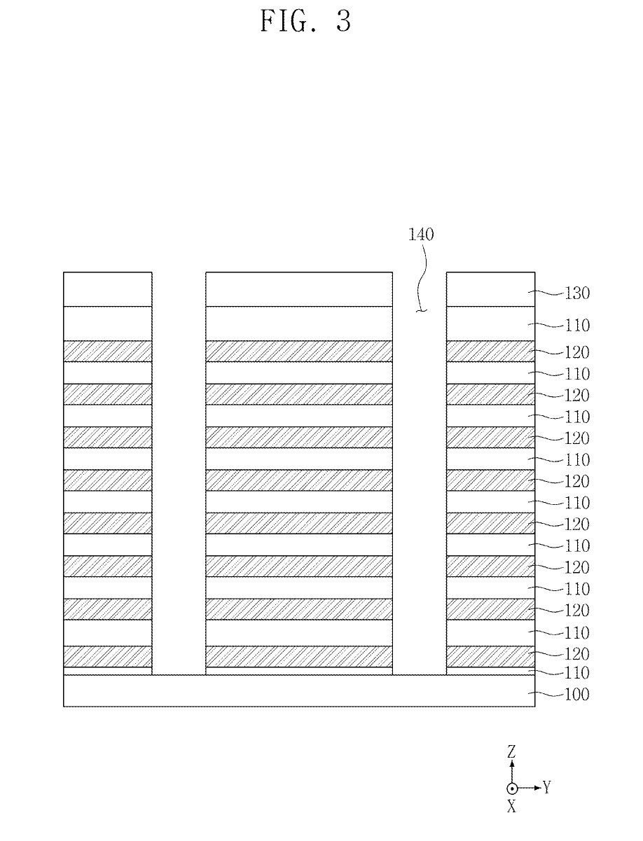

Referring to FIG. 3, the method may include forming a channel hole 140 exposing the substrate 100 through the interlayer insulating layers 110 and the sacrificial layers 120. For example, the forming the channel hole 140 may include forming a mask pattern 130 on the uppermost interlayer insulating layer 110, and anisotropic etching the interlayer insulating layers 110 and the sacrificial layers 120 until an upper surface of the substrate 100 is exposed using the mask pattern 130 as an etch mask. The channel hole 140 may have various shapes such as a circular shape, an elliptic shape, or a polygonal shape in a top view. The mask pattern 130 may include a photoresist pattern or a hardmask pattern. The mask pattern 130 may be removed after the channel hole 140 is formed

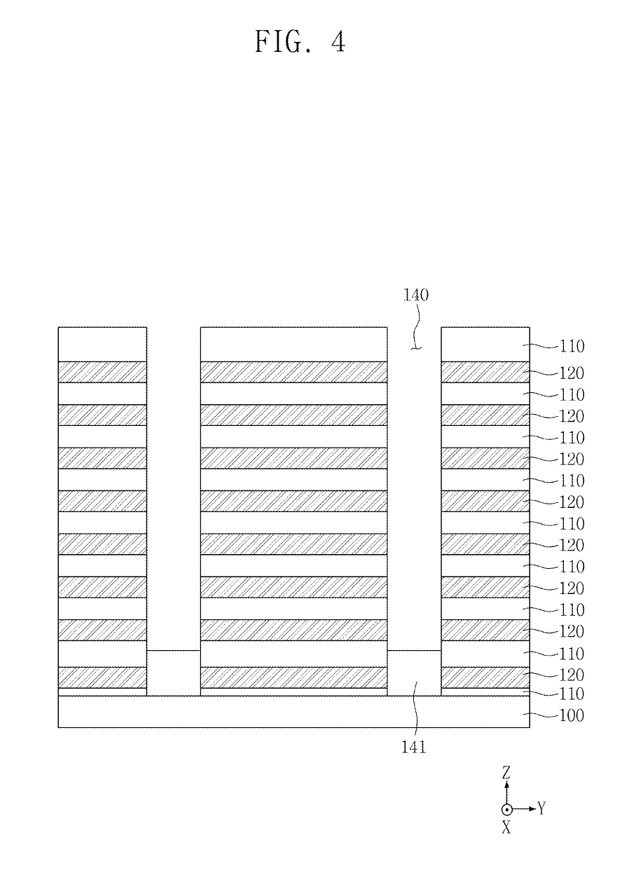

Referring to FIG. 4, the method may include forming a semiconductor pattern 141 partially filling a lower portion of the channel hole 140. For example, the semiconductor pattern 141 partially filling a bottom surface of the channel hole 140 may be formed by performing a selectively epitaxial growth (SEG) process using an upper surface of the substrate 100 as a seed exposed by the channel hole 140. The semiconductor pattern 141 may include single crystalline silicon or single crystalline silicon-germanium, and include doped impurity ions in some cases. An upper surface of the semiconductor pattern 141 may be located at a higher level than an upper surface of the lowest sacrificial layer 120.

Referring to FIGS. 5A and 5B, the method may include sequentially forming a first blocking insulating layer 151, a second blocking insulating layer 152, an electric charge trap layer 161 and a tunnel insulating layer 162 on a sidewall of the channel hole 140, the uppermost interlayer insulating layer 110 and the semiconductor pattern 141. The first blocking insulating layer 151 and the second blocking insulating layer 152 are illustrated as one blocking insulating layer 150, and the electric charge trap layer 161 and the tunnel insulating layer 162 are illustrated as one electric charge storage layer 160 in FIG. 2D. The first blocking insulating layer 151 and the second blocking insulating layer 152 may include insulating layers having different etch rates from each other for an etchant. For example, the first blocking insulating layer 151 and the second blocking insulating layer 152 may include silicon oxide (SiO₂) having different etch rates in hydrofluoric acid (HF). The first blocking insulating layer 151 and the second blocking insulating layer 152 may be formed by different formation methods from each other. For example, the first blocking insulating layer 151 may include silicon oxide (SiO₂) formed by a chemical vapor deposition method. The second blocking insulating layer 152 may include silicon oxide (SiO₂) changed from silicon nitride (SixNy) by a radical oxidation process. The silicon oxide (SiO₂) formed by the radical oxidation process may have similar characteristics to thermally oxidized silicon. Thus, the second blocking insulating layer 152 may be denser and harder than the first blocking insulating layer 151. The second blocking insulating layer 152 may have a thickness greater than or equal to the first blocking insulating layer 151.

The electric charge storage layer 160 may include the electric charge trap layer 161 and the tunnel insulating layer 162. The electric charge trap layer 161 may include a nitride such as silicon nitride. The tunnel insulating layer 162 may include silicon oxide or silicon oxynitride.

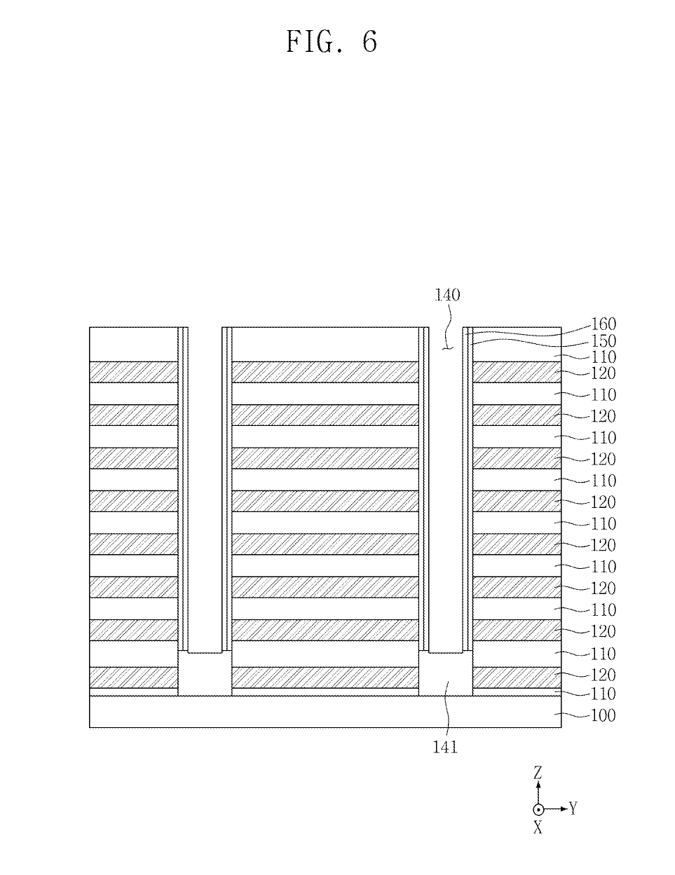

Referring to FIG. 6, the method may include anisotropic etching the blocking insulating layer 150 and the electric charge storage layer 160, and exposing an upper surface of the uppermost interlayer insulating layer 110 and an upper surface of the semiconductor pattern 141. When the anisotropic etching is performed, the blocking insulating layer 150 and the electric charge storage layer 160 having a spacer shape may remain on the sidewall of the channel hole 140. The exposed upper surface of the semiconductor pattern 141 may be recessed.

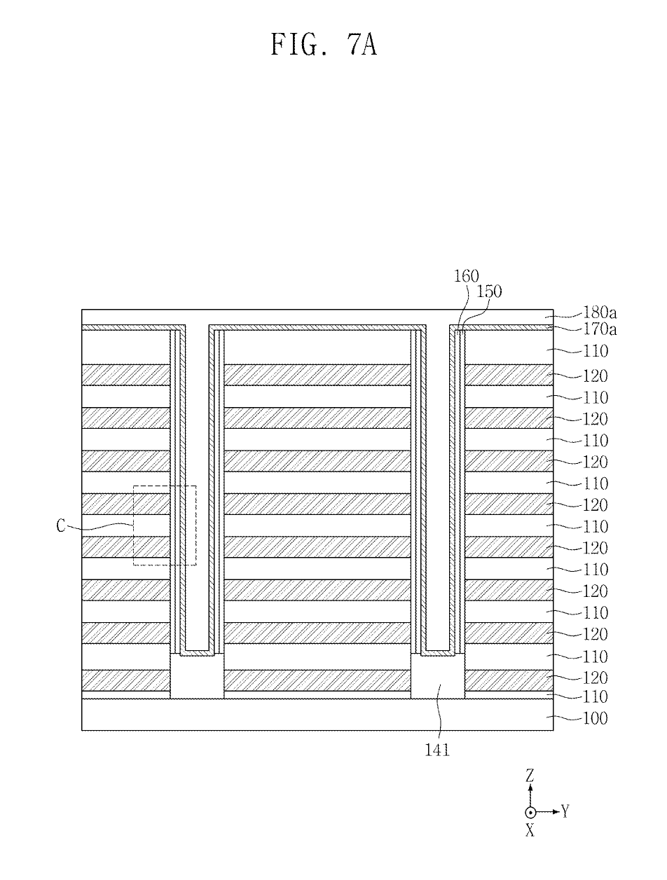

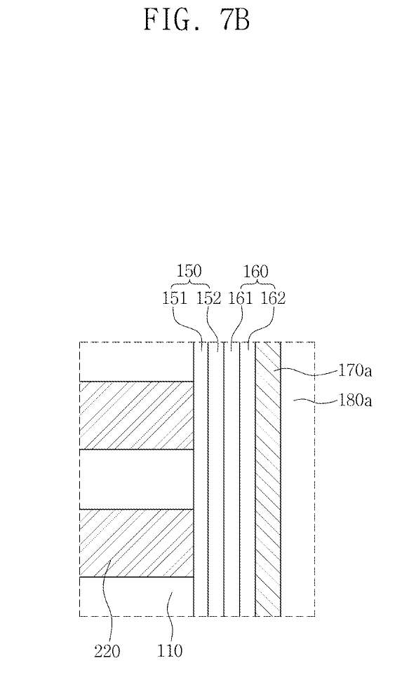

Referring to FIGS. 7A and 7B, the method may include forming a channel layer 170a and a filling insulating layer 180a in the channel hole 140. The channel layer 170a may be formed on the uppermost interlayer insulating layer 110, the sidewall of the channel hole 140 and the exposed semiconductor pattern 141. The channel layer 170a may be in direct contact with an upper surface of the semiconductor pattern 141 and electrically connected to the substrate 100. The channel layer 170a may include polycrystalline silicon. The filling insulating layer 180a may be formed on the channel layer 170a to fully fill the inside of the channel hole 140. The filling insulating layer 180a may include silicon oxide.

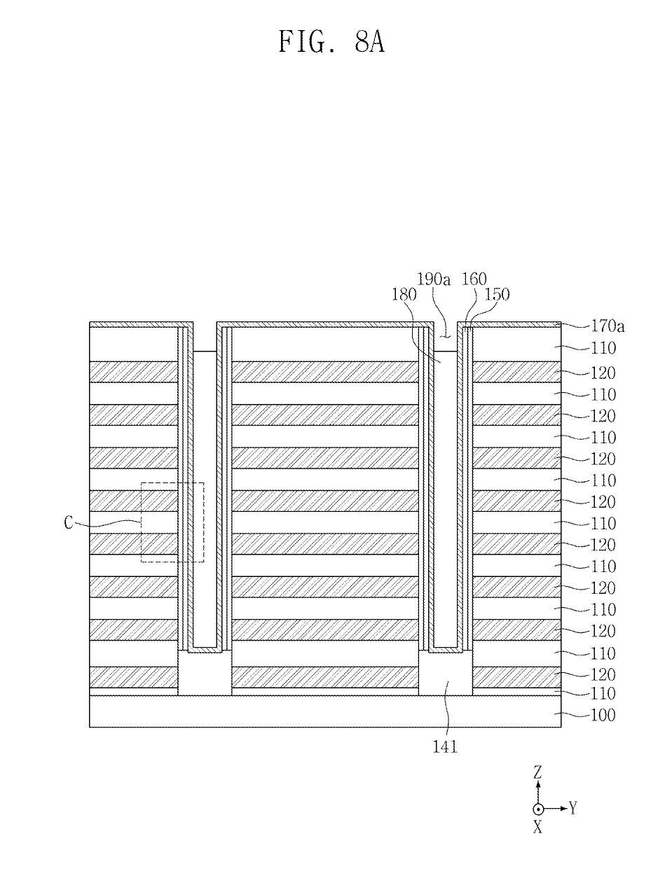

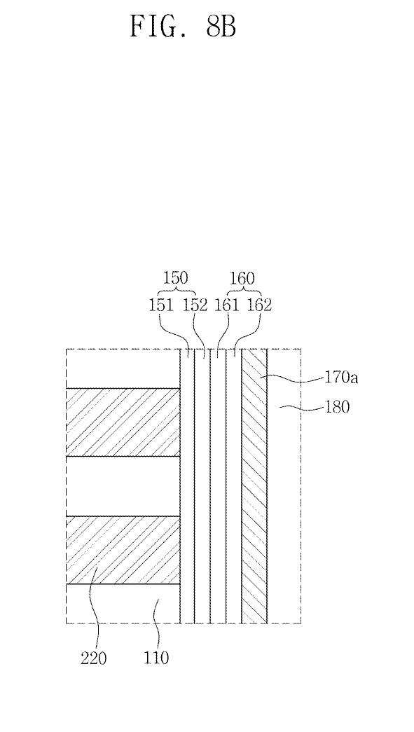

Referring to FIGS. 8A and 8B, the method may include forming a filling insulating layer pattern 180 having a pad recess 190a by performing an etch-back process on the filling insulating layer 180a. The channel layer 170a may be exposed on the uppermost interlayer insulating layer 110.

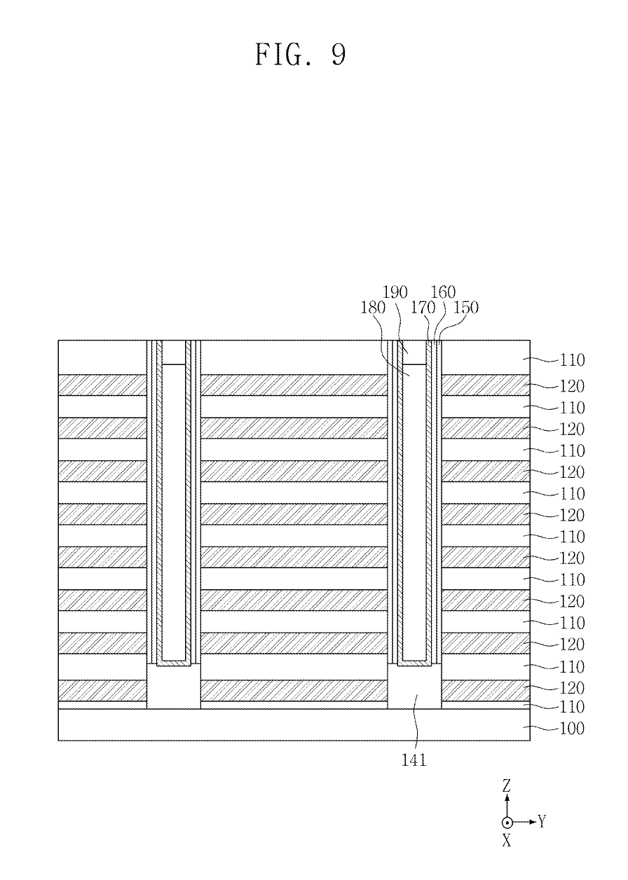

Referring to FIG. 9, the method may include filling a pad material filling the pad recess 190a, performing a chemical mechanical polishing process, and forming a vertical channel 170 and a channel pad 190. A structure in which the blocking insulating layer 150, the electric charge storage layer 160, the vertical channel 170 and the filling insulating layer pattern 180 are sequentially stacked may be formed on the sidewall of the channel hole 140. The channel pad 190 may include a conductive material such as polycrystalline silicon doped with impurities.

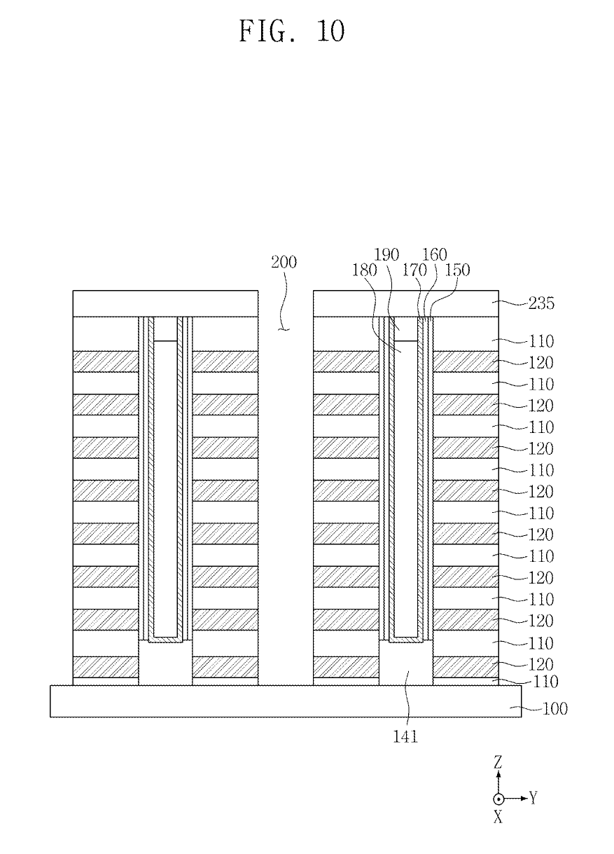

Referring to FIG. 10, the method may include forming a capping insulating layer 235, anisotropic etching the capping insulating layer 235, the interlayer insulating layers 110 and the sacrificial layers 120 between adjacent vertical channels 170, and forming a trench 200. The trench 200 may expose the substrate 100 through the interlayer insulating layers 110 and the sacrificial layers 120 in a vertical manner. The trench 200 may extend along an X direction. Side surfaces of the interlayer insulating layers 110 and the sacrificial layers 120 may be exposed on a sidewall of the trench 200.

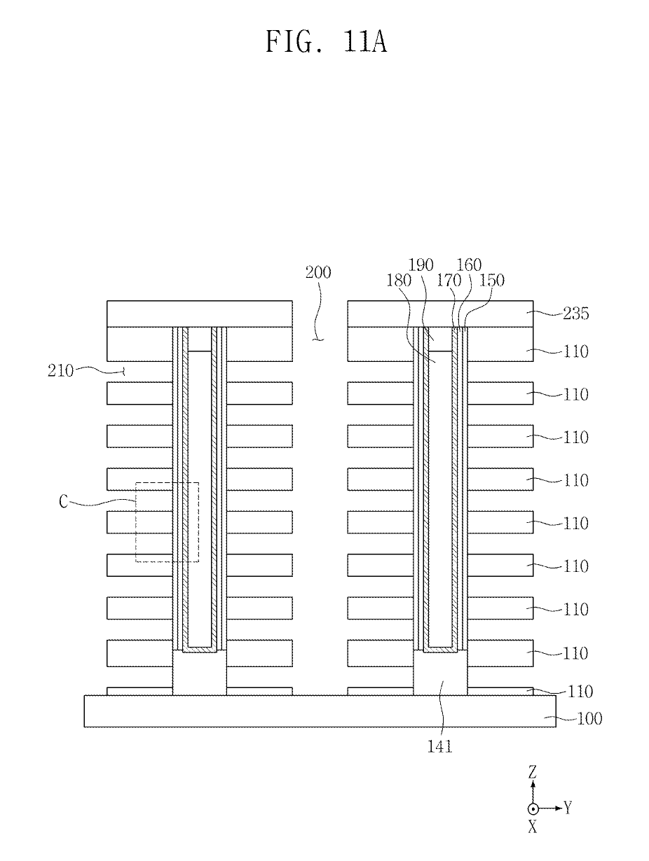

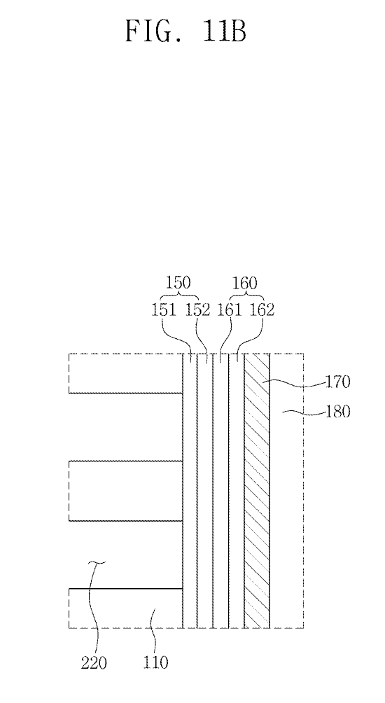

Referring to FIGS. 11A and 11B, the method may include removing the sacrificial layers 120 exposed on the sidewall of the trench 200 and forming a gap 210 between the interlayer insulating layers 110. The first blocking insulating layer 151, a portion of a sidewall of the semiconductor pattern 141, and a portion of an upper surface of substrate 100 may be exposed by the gap 210. The first blocking insulating layer 151 may be partially removed.

The removing the sacrificial layers 120 may include performing a wet etch process using a first etchant having a higher etch selectivity than the interlayer insulating layers 110. When the interlayer insulating layer 110 and the sacrificial layer 120 include a silicon oxide layer and a silicon nitride layer, respectively, the first etchant may include phosphoric acid (H₃PO₄). In some example embodiments, since the blocking insulating layer 150 includes the first blocking insulating layer 151 and the second blocking insulating layer 152, the second blocking insulating layer 152 may be protected from an attack of the phosphoric acid (H₃PO₄) by the first blocking insulating layer 151, or damage thereof may be reduced.

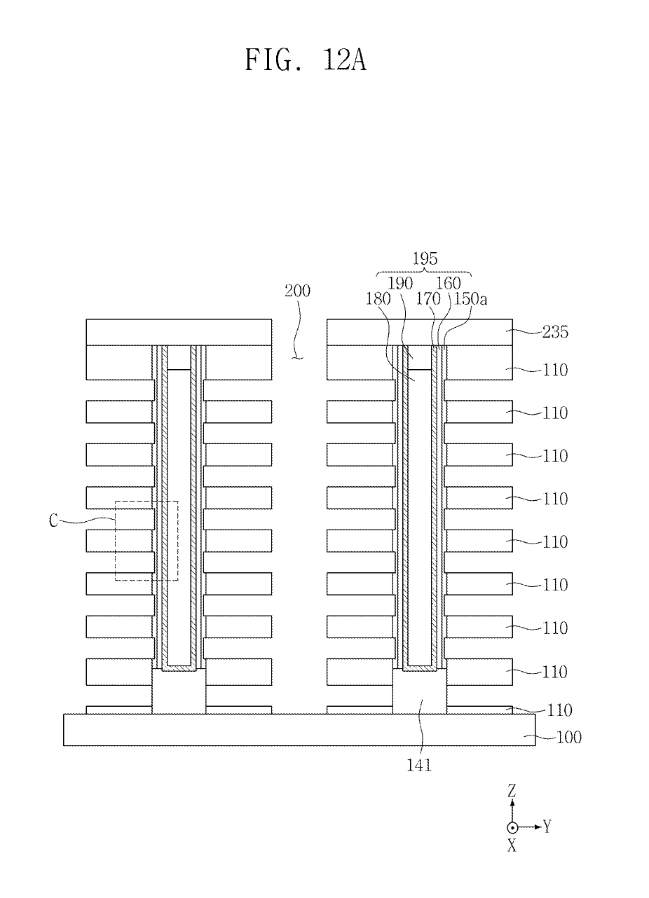

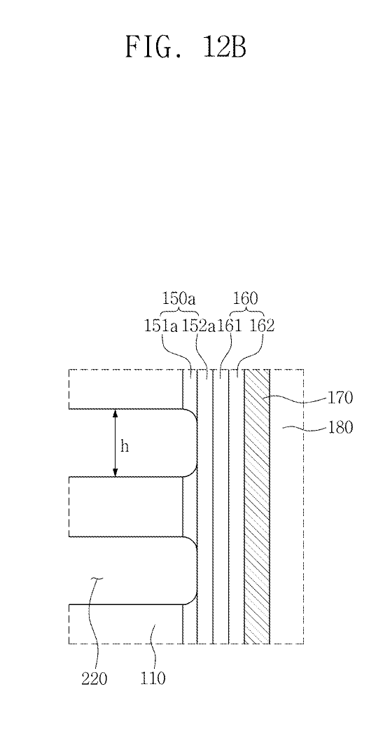

Referring to FIGS. 12A and 12B, the method may include removing the damaged first blocking insulating layer 151 and exposing the second blocking insulating layer 152. As the first blocking insulating layer 151 exposed in the gap 210 is removed, a space in the gap 210 may extend in a horizontal direction and the second blocking insulating layer 152 may be exposed. A first blocking insulating pattern 151a and a second insulating pattern 152a may be formed between the interlayer insulating layer 110 and the electric charge trap layer 161. Upper/lower surfaces of the first blocking insulating pattern 151a exposed in the gap 210 may be rounded to have a curved surface. Thus, a pillar structure 195 including the first blocking insulating pattern 151a, the second blocking insulating pattern 152a, the electric charge storage layer 160, the vertical channel 170, the filling insulating layer pattern 180 and the channel pad 190 may be formed.

The removing the first blocking insulating layer 151 exposed in the gap 210 may include performing a wet etch process using a second etchant. When the first blocking insulating layer 151 and the second blocking insulating pattern 152a include silicon oxide, the second etchant may include hydrofluoric acid (HF). The first blocking insulating layer 151 may have at least two times higher etch rate than the second blocking insulating layer 152 for the hydrofluoric acid (HF). The second blocking insulating layer 152 may uniformly remain to a thickness similar to an initially formed thickness even after the first blocking insulating layer 151 is removed. Thus, as the second blocking insulating pattern 152a may substantially serve as the blocking insulating layer 150, degradation of the characteristics of a semiconductor device may be reduced. In addition, an oxide-based interlayer insulating layer 110 is partially removed in the removing the first blocking insulating layer 151, so that the interlayer insulating layer 110 may have a smaller thickness than when the interlayer insulating layer 110 is first deposited. Thus, a height h of the gap 210 may be increased. Therefore, in the following process, a height of a gate electrode formed in the gap 210 is increased so that it may be advantageous to obtain a proper channel length.

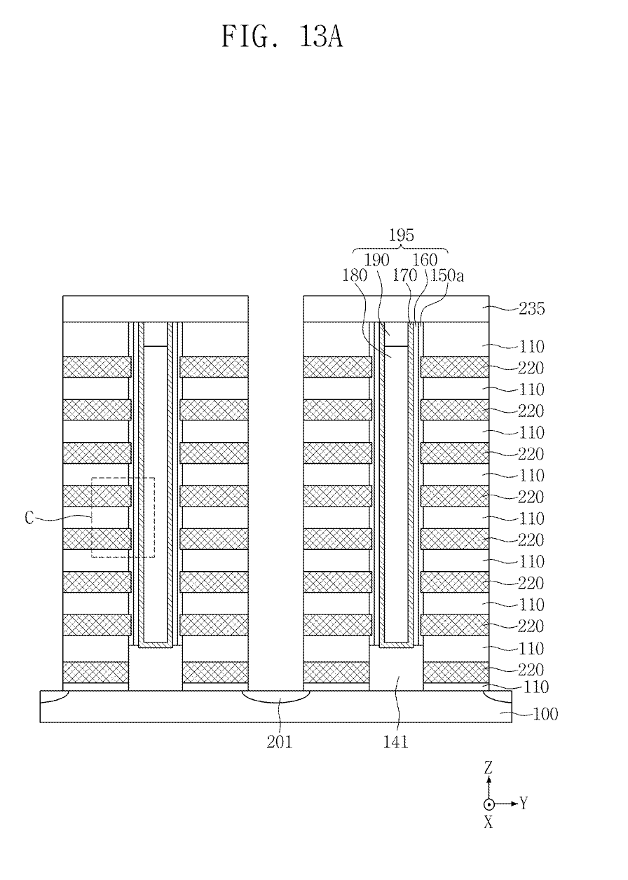

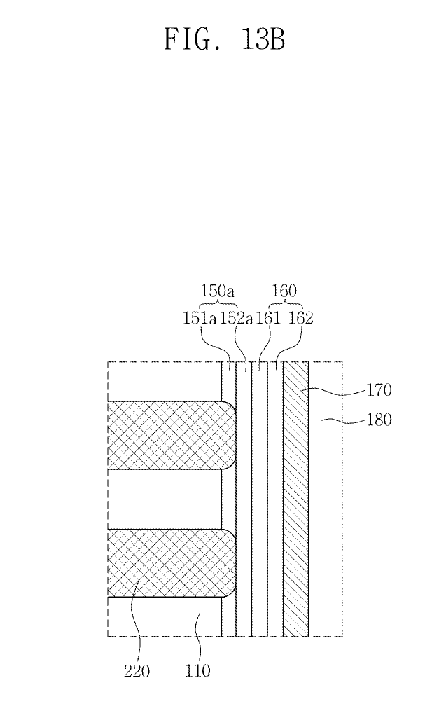

Referring to FIGS. 13A and 13B, the method may include forming gate electrodes 220 fully filling the gap 210 on the interlayer insulating layer 110, the upper and lower surfaces of the first blocking insulating pattern 151a and the second blocking insulating pattern 152a in the gap 210. The gate electrodes 220 may include a burial metal layer directly formed on an inside wall of the gap 210.

The gate electrodes 220 may be rounded to have a curved surface at a portion in contact with the upper and lower surfaces of the first blocking insulating pattern 151a. The burial metal layer may include a metal nitride such as titanium, titanium nitride, tantalum and/or tantalum nitride. The gate electrodes 220 may include a metal material such as tungsten, titanium, tantalum, platinum or a metal silicide.

Then, the method may further include injecting impurities into the substrate 100 exposed in the trench 200 and forming a common source line 201 extending in an X direction along the trench 200. The impurities may include N-type impurities such as phosphorus or arsenic.

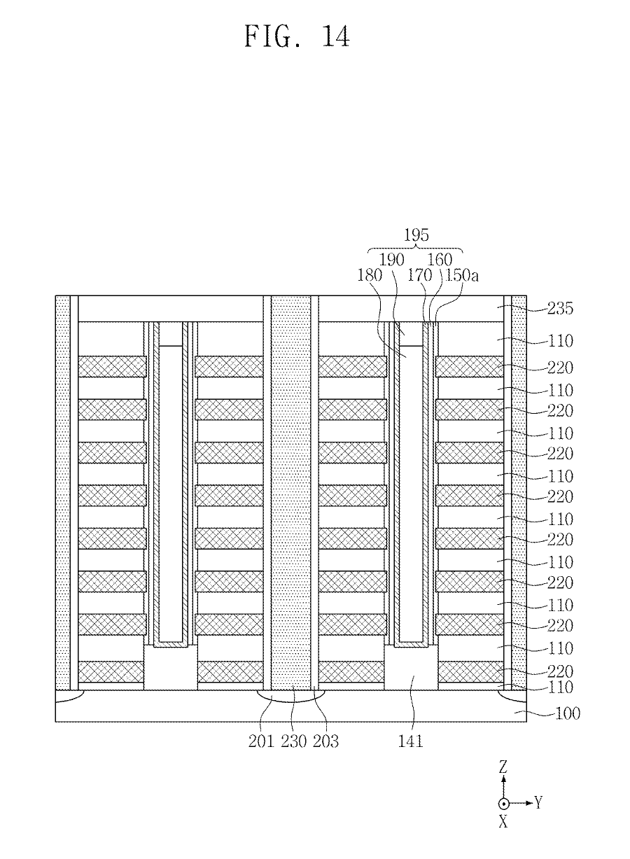

Referring to FIG. 14, the method may include forming a trench spacer 203 and a trench insulator 230 filling the trench 200 and extending in an X direction on the sidewall of the trench 200. The trench spacer 203 may include an insulating material such as silicon oxide or silicon nitride. The trench insulator 230 may include an insulating material such as silicon oxide. The method may further include performing a chemical mechanical polishing process to planarize upper surfaces of the trench insulator 230 and the capping insulating layer 235.

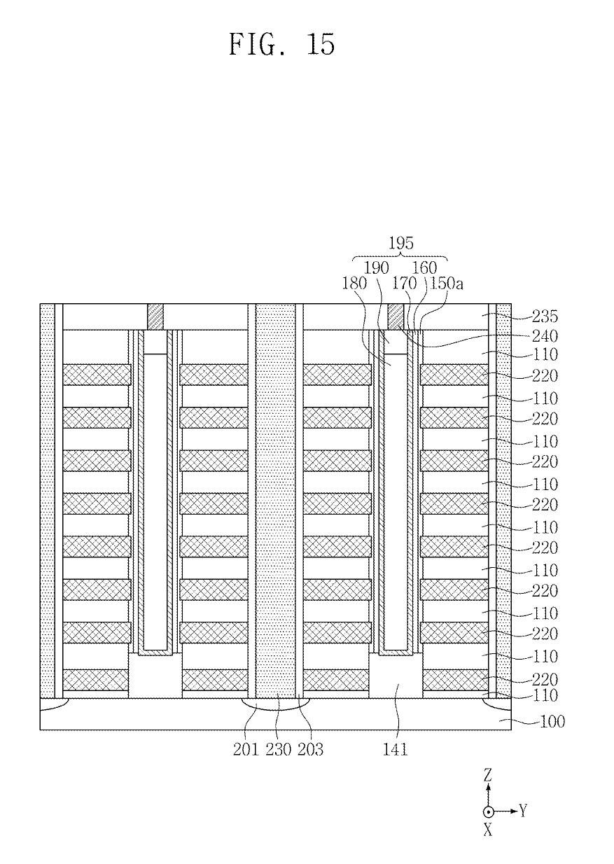

Referring to FIG. 15, the method may include forming contact holes exposing an upper surface of the channel pad 190 in the upper capping insulating layer 235, and forming a bit line contact 240 in the contact holes. The bit line contact 240 may include a metal such as tungsten or copper.

Then, referring to FIGS. 1A and 1B, the method may include forming a bit line 250 in contact with an upper surface of the bit line contact 240 and extending in a Y direction on the capping insulating layer 235. The bit line 250 may include a metal such as tungsten or copper.

In accordance with some example embodiments of the inventive concepts, as the blocking insulating layer 150 includes the first blocking insulating layer 151 and the second blocking insulating layer 152, the first blocking insulating layer 151 may prevent or reduce the second blocking insulating layer 152 from being damaged by an etchant in removing the sacrificial layers 120. The damaged first blocking insulating layer 151 is removed and then the second blocking insulating layer 152 may be used as an insulating layer for substantially blocking.

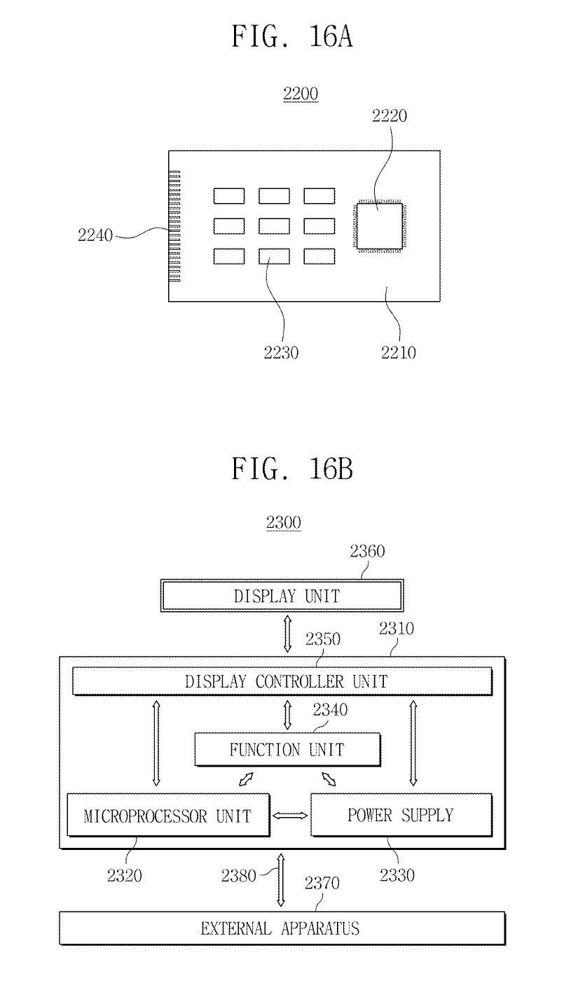

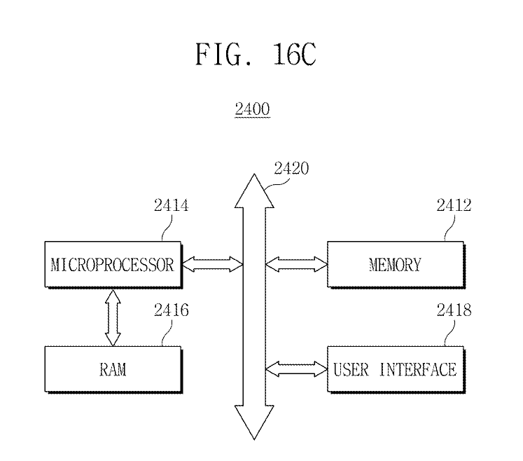

FIG. 16A is a diagram conceptually illustrating a semiconductor module 2200 in accordance with embodiments of the inventive concepts. Referring to FIG. 16A, the semiconductor module 2200 in accordance with embodiments of the inventive concepts may include a processor 2220 and semiconductor devices 2230 mounted on a module substrate 2210. The processor 2220 or the semiconductor devices 2230 may include the semiconductor device 1000 in accordance with various embodiments of the inventive concepts. Input/output terminals 2240 may be disposed on at least one side of the module substrate 2210.

FIGS. 16B and 16C are block diagrams conceptually illustrating electronic systems 2300 and 2400 in accordance with embodiments of the inventive concepts. Referring to FIG. 16B, the electronic system 2300 in accordance with embodiments of the inventive concepts may include a body 2310, a display unit 2360 and an external apparatus 2370.

The body 2310 may include a microprocessor unit 2320, a power supply 2330, a function unit 2340 and/or a display control unit 2350. The body 2310 may include may include a system board or mother board having a printed circuit board (PCB), and/or a case. The microprocessor unit 2320, the power supply 2330, the function unit 2340 and the display control unit 2350 may be mounted or disposed on an upper surface of the body 2310 or in the body 2310. The display unit 2360 may be disposed on the upper surface of the body 2310 or inside/outside of the body 2310.

The display unit 2360 may display an image processed by the display control unit 2350. For example, the display unit 2360 may include a liquid crystal display (LCD), an active matrix organic light emitting diodes (AMOLED), or various display panels. The display unit 2360 may include a touch screen. Thus, the display unit 2360 may have input/output functions.

The power supply 2330 may supply a current or voltage to the microprocessor unit 2320, the function unit 2340, the display control unit 2350, etc. The power supply 2330 may include a charging battery, a socket for a dry cell, or a voltage/current transformer.

The microprocessor unit 2320 may receive a voltage from the power supply 2330 and control the function unit 2340 and the display unit 2360. For example, the microprocessor unit 2320 may include a central processing unit (CPU) or an application processor (AP).

The function unit 2340 may perform various functions of the electronic system 2300. For example, the function unit 2340 may include a touch pad, a touch screen, a volatile/non-volatile memory, a memory card controller, a camera, a light, a voice and a moving picture reproducing processor, a wireless two-way antenna, a speaker, a microphone, a USB port, or a unit having other various functions.

The microprocessor unit 2320 or the function unit 2340 may include the semiconductor device 1000 in accordance with embodiments of the inventive concepts.

Referring to FIG. 16C, the electronic system 2400 in accordance with embodiments of the inventive concepts may include a microprocessor 2414, a memory system 2412 and a user interface 2418 which perform a data communication through a bus 2420. The microprocessor 2414 may include a CPU or an AP. The electronic system 2400 may further include a random access memory (RAM) 2416 in direct communication with the microprocessor 2414. The microprocessor 2414 and/or the RAM 2416 may be assembled in a single package. The user interface 2418 may be used to input information to the electronic system 2400 or output information from the electronic system 2400. For example, the user interface 2418 may include a touch pad, a touch screen, a keyboard, a mouse, a scanner, a voice detector, a cathode ray tube (CRT) monitor, an LCD, an AMOLED, a plasma display panel (PDP), a printer, a light, or other various input/output apparatuses. The memory system 2412 may store operating codes of the microprocessor 2414, data processed by the microprocessor 2414, or an external input data. The memory system 2412 may include a memory controller, a hard disk, or a solid state drive (SSD). The microprocessor 2414, the RAM 2416 and/or the memory system 2412 may include the semiconductor device 1000 in accordance with embodiments of the inventive concepts.

In some embodiments, as a vertical-type semiconductor memory device in accordance with embodiments of the inventive concepts includes a double-layered blocking insulating layer, a first blocking insulating layer damaged while fabricating a semiconductor device is removed, so that a second blocking insulating layer which has no damage while fabricating thereof can be formed. Therefore, characteristic degradation of the vertical-type semiconductor memory device can be prevented or reduced.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of these inventive concepts as defined in the claims. In the claims, means-plus-function clauses are intended to cover the structures described herein as performing the recited function, and not only structural equivalents but also equivalent structures.

What is claimed is:

1. A method of fabricating a semiconductor memory device, comprising:
alternately stacking interlayer insulating layers and sacrificial layers on a substrate;
forming a channel hole exposing the substrate through the interlayer insulating layers and the sacrificial layers;
sequentially forming a blocking insulating layer, an electric charge storage layer and a channel layer on the substrate exposed on a sidewall of the channel hole and in the channel hole, wherein the blocking insulating layer includes a first blocking insulating layer and a second blocking insulating layer;
selectively removing the sacrificial layers to expose the first blocking insulating layer and forming a gap;
removing the first blocking insulating layer exposed in the gap, and forming first blocking insulating patterns between the interlayer insulating layers and the second blocking insulating layer; and
forming a gate electrode in the gap.

2. The method of claim 1, further comprising forming a semiconductor pattern between the substrate and the channel layer in the channel hole.

3. The method of claim 1, wherein a portion of the gate electrode in contact with the first blocking insulating patterns is rounded to have a curved surface.

4. The method of claim 1, wherein the second blocking insulating layer is denser than the first blocking insulating layer.

5. The method of claim 1, wherein the first blocking insulating layer has at least two times higher etch rate than the second blocking insulating layer for hydrofluoric acid (HF).

6. The method of claim 1, wherein the forming the second blocking insulating layer includes forming a silicon nitride layer, performing a radical oxidation process and changing the silicon nitride layer to a silicon oxide layer.

7. The method of claim 1, wherein the forming the first blocking insulating layer includes performing a chemical vapor deposition process or an atomic layer deposition process and forming a silicon oxide layer.

8. The method of claim 1, wherein the electric charge storage layer includes an electric charge trap layer including a silicon nitride layer or a silicon oxynitride layer, and a tunnel insulating layer including a silicon oxide layer or a silicon oxynitride layer.

9. The method of claim 1, wherein the channel layer includes polycrystalline silicon.

10. The method of claim 1, wherein the second blocking insulating layer has a thickness greater than or equal to the first blocking insulating layer.

11. The method of claim 1, wherein the second blocking insulating layer is vertically continued.

12. The method of claim 1, wherein the first blocking insulating pattern is vertically discontinued.

13. The method of claim 1, wherein the first blocking insulating pattern is disposed between gate electrodes stacked in a vertical direction on the substrate.

14. The method of claim 1, wherein the first blocking insulating patterns are formed between the interlayer insulating layers and the electric charge storage layer.

15. A method of fabricating a semiconductor memory device, comprising:
alternately stacking a plurality of interlayer insulating layers and a plurality of sacrificial layers on a substrate;
forming at least two channel holes exposing a first surface of the substrate through the plurality of interlayer insulating layers and the plurality of sacrificial layers;
forming pillar structures in the at least two channel holes, wherein each of the pillar structures includes a first blocking insulating layer, a second blocking insulating layer, an electric charge trap layer, a tunnel insulating layer, a vertical channel and a filling insulating layer;
forming a trench passing through the plurality of interlayer insulating layers and the plurality of sacrificial layers between the pillar structures, wherein the trench exposes side surfaces of the plurality of interlayer insulating layers and the plurality of sacrificial layers and a second surface of the substrate;
removing the plurality of sacrificial layers exposed in the trench and forming a gap;
removing the first blocking insulating layer exposed in the gap, and exposing the second blocking insulating layer in the gap;
forming a gate electrode in the gap; and
forming a trench insulator in the trench.

16. The method of claim 15, wherein the forming the second blocking insulating layer includes:
forming a silicon nitride layer,
performing a radical oxidation process and
changing the silicon nitride layer to a silicon oxide layer.

17. The method of claim 15, wherein the second blocking insulating layer has a thickness greater than or equal to the first blocking insulating layer.

18. A method of fabricating a semiconductor memory device, comprising:
alternately stacking interlayer insulating layers and sacrificial layers on the substrate;
forming a channel hole exposing the substrate through the interlayer insulating layers and sacrificial layers;
forming a semiconductor pattern partially filling a lower portion of the channel hole;
sequentially forming a blocking insulating layer, an electric charge storage layer and a channel layer on a sidewall of the channel hole and on the semiconductor pattern, wherein the blocking insulating layer includes a first blocking insulating layer and a second insulating layer;
selectively removing the sacrificial layers to expose the first blocking insulating layer and a sidewall of the semiconductor pattern and forming a gap;
removing the first blocking insulating layer exposed in the gap and forming first blocking insulating patterns between the interlayer insulating layers and the second blocking layer, upper and lower surfaces of the first blocking insulating patterns being rounded to have a curved surface; and
forming a gate electrode in the gap.

19. The method of claim 18, wherein a distance from a side surface of the gate electrode to the channel layer is shorter than a distance from a side surface of the interlayer insulating layers to the channel layer.

20. The method of claim 18, wherein the gate electrode disposed on the lowest portion surrounds an outside wall of the semiconductor pattern.
